(19) United States
(12) Patent Application Publication
(10) Pub. No.: US 2026/0290424 A1
(43) Pub. Date: Sep. 24, 2026

(54) MEMORY MODULE POWER CONTROL APPARATUS AND MEMORY POWER CONTROL APPARATUS

(71) Applicant: Chae Kyu JANG, Suwon-si Gyeonggi-do (KR)

(72) Inventor: Chae Kyu JANG, Suwon-si Gyeonggi-do (KR)

(21) Appl. No.: 18/874,068

(22) PCT Filed: Jan. 30, 2024
(86) PCT No.: PCT/KR2024/001375

§ 371 Date: Dec. 11, 2024

(30) Foreign Application Priority Data
Feb. 6, 2023 (KR) 10-2023-0015305

(51) Int. Cl. G11C 11/4074; G11C 11/4076

(52) U.S. Cl. CPC G11C 11/4074; G11C 11/4076; G11C 2207/2227; G11C 2207/2272

(57) ABSTRACT

A memory module power control apparatus and a memory power control apparatus are provided. The memory module power control apparatus according to an embodiment of the present inventive concept comprises the memory module power control apparatus comprising: a command decoder which a command line is connected to and decodes a memory command being delivered from a memory controller to a memory; a regulator that supplies a current to the memory; a register that stores a parameter for adjusting an output of the regulator; and a control unit that controls, on the basis of the decoded command, to configure the parameter and store the parameter in the register, according to the memory command being input into the memory.

### TECHNICAL FIELD

The present inventive concept relates to a memory module power control apparatus and a memory power control apparatus, and more particularly, to a memory module power control apparatus and a memory power control apparatus, which can decode a DRAM command and adjust power driving capability and response time suitable for DRAM operation.

### BACKGROUND ART

Recently, as the computing speed of CPU has increased, the capacity of DRAM is expanded to 16 G or more in the server class presently. As the capacity of DRAM increases, the number of rows to be refreshed increases. Therefore, current consumed by the DRAM increases.

Meanwhile, in modules lower than Double Data Rate 4(DDR4), the Power Management IC (PMIC) that supplies DRAM power is located on the main board, which is external to the DRAM module. Therefore, it is easy to supply DRAM power from the PMIC located on the main board. However, in the modules higher than DDR5, the PMIC is installed in each DRAM module, and a single PMIC manages power used by the DRAM in the corresponding module. In addition, as the DRAM speed after DDR5 increases, power supply capability and response time of the PMIC need to be improved. However, since the PMIC for DRAM until present applies a design scheme for stably supplying power at all times regardless of operation of the DRAM, there are restrictions in the specifications, and it is also disadvantageous to change the settings through I2C/I3C ports as time and manpower are required.

Therefore, it is required to provide a means that can reduce standby power of the PMIC as it has a capability of supplying minimum power and fast response time when the DRAM does not maximally use current, and allows the PMIC to supply maximum power and have the fastest response time to stably supply power in an operation when the DRAM uses current to the maximum.

### DISCLOSURE OF INVENTIVE CONCEPT

### Technical Problem

Therefore, the present inventive concept has been made in view of the above problems, and it is an object of the present inventive concept to provide a memory module power control apparatus and a memory power control apparatus, which can decode a DRAM command and adjust power driving capability and response time suitable for DRAM operation.

### Technical Solution

To accomplish the above object, according to one aspect of the present inventive concept, there is provided a memory module power control apparatus comprising: a command decoder connected with a command line to decode a memory command transferred from a memory controller to a memory; a regulator for supplying current to the memory; a register for storing a parameter that adjusts an output of the regulator; and a control unit for controlling to set and store the parameter in the register according to the memory command input into the memory on the basis of the decoded command.

In an embodiment, the memory module power control apparatus may include a Mode Register Write (MRW) command, a refresh command, a write command, a read command, and an active/precharge command.

In an embodiment, the control unit may set the register according to the MRW command, and sets the register to adjust the output of the regulator according to the refresh command, the write command, the read command, and the active/precharge command.

In an embodiment, the memory module power control apparatus may further comprise a counter for counting the number of generating the refresh transferred to the memory, wherein the control unit sets the register to adjust the output of the regulator according to the number of refreshes counted by the counter.

In an embodiment, the control unit may
control to minimize the output of the regulator between a previous refresh command set and a next refresh command set,
control driving of the regulator by the parameter stored in the register to be enabled before a refresh operation of the memory according to execution of the refresh command and disabled after the refresh operation of the memory is completed in response to the refresh command, and
control a driving time point of the regulator for the write command and the read command by considering Write Latency (CWL) and Read Latency (CL).

According to another aspect of the present inventive concept, there is provided a memory power control apparatus comprising: a command decoder provided in a memory to decode a memory command transferred from a memory controller; a regulator for supplying current to a power circuit provided inside the memory; a register for storing a parameter that adjusts an output of the regulator; and a control unit for controlling to set and store the parameter in the register according to the memory command input into the memory on the basis of the decoded command.

### Advantageous Effects

As the memory module power control apparatus and the memory power control apparatus according to an embodiment of the present inventive concept may adjust power driving capability and response time suitable for memory operation by themselves by receiving and decoding a memory command, current consumption can be reduced.

In addition, as the memory module power control apparatus and the memory power control apparatus according to an embodiment of the present inventive concept may prepare for current consumption suitable for each operation by changing internal settings in advance during normal operation of the memory, malfunctions due to current shortage or overcurrent can be minimized.

In addition, as the memory module power control apparatus and the memory power control apparatus according to an embodiment of the present inventive concept may operate stably by utilizing internal resources by counting the number of refreshes and adjusting the output according to the number of refreshes, stability of products can be improved.

In addition, as the memory module power control apparatus and the memory power control apparatus according to an embodiment of the present inventive concept may minimize power consumption by selectively enabling the driving circuit or controlling the driving time point according to a command operation, cost can be reduced by reducing current consumption of the entire system.

### BRIEF DESCRIPTION OF THE DRAWINGS

FIG. 1 is a view showing the configuration of a memory module having a memory module power control apparatus according to an embodiment of the present inventive concept.

FIG. 2 is a view showing the configuration of an example of a memory module having a memory module power control apparatus according to an embodiment of the present inventive concept.

FIG. 3 is a view showing the configuration of another example of a memory module having a memory module power control apparatus according to an embodiment of the present inventive concept.

FIG. 4 is a view showing the configuration of a refresh count unit of a memory module power control apparatus according to an embodiment of the present inventive concept.

FIG. 5 is a timing diagram for explaining the refresh count of a memory module power control apparatus according to an embodiment of the present inventive concept.

FIG. 6 is a timing diagram for explaining changes in driving capability according to the number of refresh inputs input at a time in a memory module power control apparatus according to an embodiment of the present inventive concept.

FIG. 7 is a view showing the configuration of a memory having a memory power control apparatus according to another embodiment of the present inventive concept.

### BEST MODE FOR CARRYING OUT THE INVENTIVE CONCEPT

Hereinafter, embodiments of the present inventive concept will be described in detail with reference to the attached drawings so that those skilled in the art may easily practice the present inventive concept. The present inventive concept may be implemented in various different forms and is not limited to the embodiments described herein. In the drawings, in order to clearly describe the present inventive concept, parts that are not related to the description will be omitted, and the same reference numerals will be assigned to the same or similar components throughout the specification.

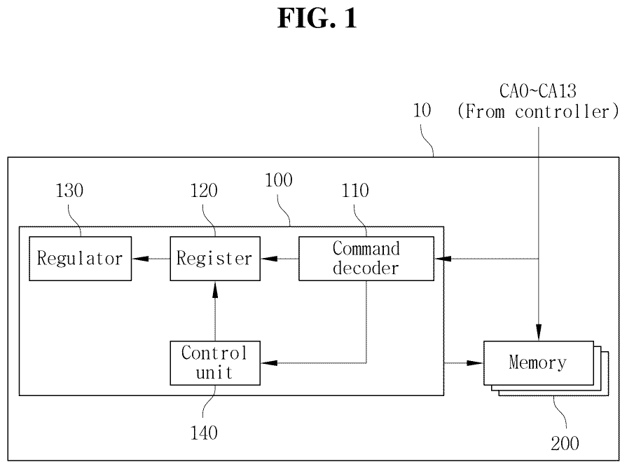

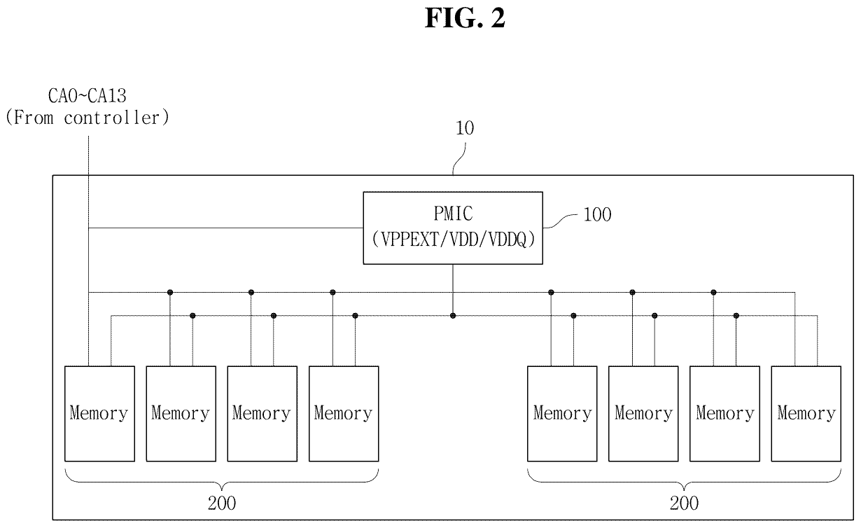

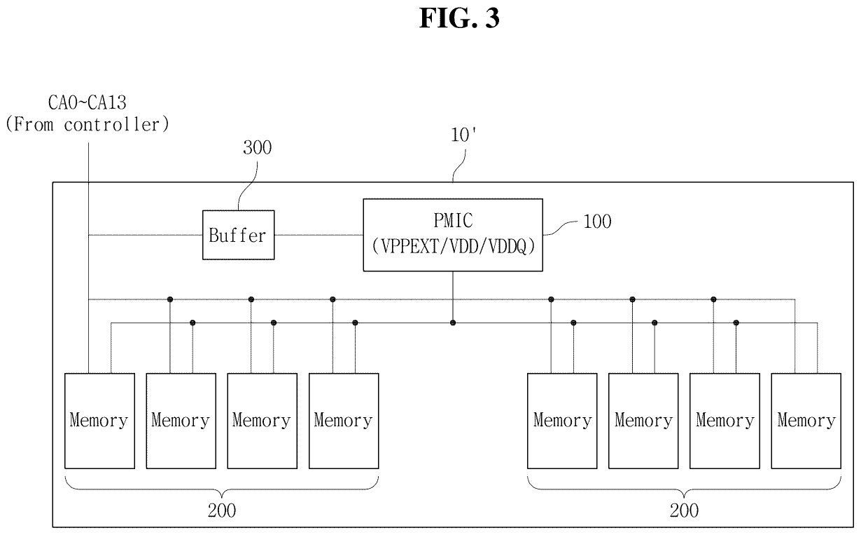

Hereinafter, a memory module power control apparatus according to an embodiment of the present inventive concept will be described in more detail with reference to the drawings. FIG. 1 is a view showing the configuration of a memory module having a memory module power control apparatus according to an embodiment of the present inventive concept, FIG. 2 is a view showing the configuration of an example of a memory module having a memory module power control apparatus according to an embodiment of the present inventive concept, and FIG. 3 is a view showing the configuration of another example of a memory module having a memory module power control apparatus according to an embodiment of the present inventive concept.

Referring to FIG. 1, a memory module power control apparatus 100 according to an embodiment of the present inventive concept includes a command decoder 110, a register 120, a regulator 130, and a control unit 140.

The memory module power control apparatus 100 is a PMIC embedded in a DDR5 or higher module, which is a memory PMIC that can control power driving capability and response time suitable for each memory operation by decoding a command using a command line (CMD Line) of the memory inside the DDR5. Here, a memory module 10 may support DDR5 or higher products. That is, the memory module 10 may include the memory module power control apparatus 100 and a memory 200. At this point, the memory 200 may be any type of memory including DRAM.

To satisfy these specifications, the memory module power control apparatus 100 may increase the driving capability and speed up the response speed according to operation of the memory 200.

For example, the memory module power control apparatus 100 may count the number of refresh commands input at one time, which use the most power in the memory.

Since the memory module power control apparatus 100 operates in a standby situation, in which power consumption and response time are set small for each operation mode, and in a normal active situation during a normal operation before a refresh is input, it has a minimum current driver size and a slow response time.

Thereafter, when a first refresh is input, the memory module power control apparatus 100 counts the input refresh using a counter 150 and stores it in a register.

Thereafter, the module power control apparatus 100 may prepare for a large current consumption to be input later by reducing the current driver size and response time in advance before the refresh is input by using an internal delay circuit according to the result of register information where the counter information is stored. Here, the memory module power control apparatus 100 may enter the standby and normal operation mode again after the refresh is finished.

The memory module power control apparatus 100 of the present inventive concept may receive a DRAM command (CS_n, CA0 to CA4, CKE) as an input, recognize operation settings of all DRAMs in the DRAM MRS by decoding the Mode Register Set (MRS), and store information needed to control power driving and response time to be suitable for DRAM operation.

According thereto, the memory module power control apparatus 100 may change the internal settings in advance when a normal operation (active/write/read/precharge) of the DRAM is input to prepare for consumption of power current suitable for each operation. For example, the memory module power control apparatus 100 may adjust VPPEXT for active/precharge operation, VDD for sensing operation, and VDDQ/VDD for write/read operation.

Since the memory module power control apparatus 100 knows in advance the refresh input timing for auto refresh that consumes a lot of power through the counter 150, stable operation of the DRAM is allowed as internal resources are used in preparation for large current consumption during refresh.

Since current consumption is currently a major issue in computing, data server, and mobile environments, as the memory module power control apparatus 100 may reduce current consumption of the entire system by reducing current consumption for operation, the cost can be reduced.

Referring to FIG. 2, the DDR5 memory module 10 may include the memory module power control apparatus 100 and the DRAM memory 200. Here, the memory module power control apparatus 100 may supply power through the VDD/VPPEXT/VDDQ power lines of the DRAM. At this point, the memory module power control apparatus 100 may receive a DRAM command through command lines CA0 to CA13 output from a memory controller (not shown).

Referring to FIG. 3, the DDR5 memory module 10′ is the same as the configuration of FIG. 2 except the buffer 160. Here, the memory module power control apparatus 100 is another embodiment that may reduce the load of a memory command signal by adding the buffer 160 that uses a command as an input.

Referring to FIG. 1 again, the command decoder 110 may be connected to the command lines CA0 to CA13 of the memory 200. The command decoder 110 may decode the memory command input through the command lines CA0 to CA13.

The register 120 may store parameters that store output of the regulator 130. That is, the register 120 may store parameters according to the memory command decoded by the command decoder 110. Here, the parameters may include a current driving magnitude and a response time.

The regulator 130 may supply current to the memory 200. That is, the regulator 130 may generate current according to the memory command and supply the current to the memory 200. In addition, the regulator 130 may generate and supply power to the memory 200 through the VDD/VPPEXT/VDDQ power lines of the DRAM.

The control unit 140 may control to set the parameters according to the amount of current required by the memory 200 based on the command decoded by the command decoder 110. That is, the control unit 140 may set a parameter for supplying current to the memory 200 according to the memory command. At this point, the control unit 140 may control to store the set parameter in the register 120. Here, the memory command may include a Mode Register Write (MRW) command, a refresh command, a write command, a read command, and an active/precharge command.

As described above, as the memory module power control apparatus 100 according to an embodiment of the present inventive concept may adjust the power driving capability and response time suitable for memory operation of the DRAM or the like by receiving and decoding a DRAM command, current consumption can be reduced.

The control unit 140 may control to set a register according to the MRW command. For example, after power-on of the memory 200, the control unit 140 receives MRS+parameter setting values according to the MRW command to set CAS (READ) Latency (CL), CAS (WRITE) Latency (CWL), Burst Length (BL), and refresh related to the basic operation of the memory 200, and parameters related to interface characteristics.

That is, since the memory module power control apparatus 100 knows settings of the MRS value and the DRAM parameters in advance according to the decoded command, it may selectively control the parts that require adjustment of the VDD/VPPEXT/VDDQ power driving and response time to allow efficient operation. At this point, the control unit 140 may adjust the VDD/VPPEXT/VDDQ power driving and response time through the setting of the MRS value and the DRAM parameters.

The control unit 140 may set the register 120 to adjust the output of the regulator 130 according to a refresh command, a write command, and a read command.

For example, when a refresh command that uses the most power in the memory 200 is input, the control unit 140 may control to increase the driving capability and response speed of the VPPEXT/VDD power.

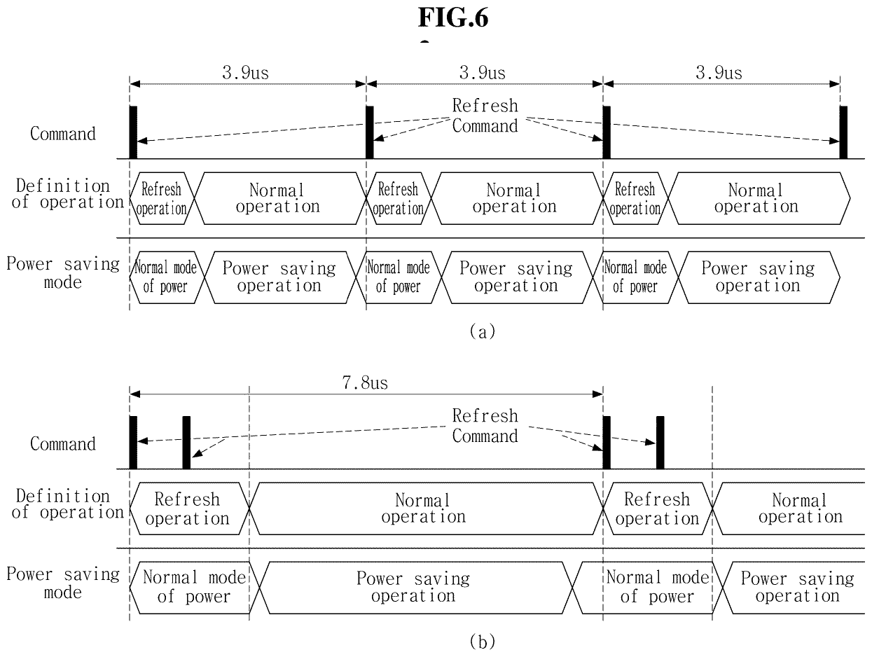

As the first refresh operation is completed within tREFC, which is a DRAM specification, the memory module power control apparatus 100 also returns to the normal mode at this point. Although the refresh is basically set to input once every 32 ms/8 K=3.9 μs, it can be input up to 8 times at tREFC intervals according to the SoC. Referring to FIG. 6, in the case of 1-piled refresh, the refresh is input once every 3.9 μs, and in the case of 2-piled refresh, the refresh is input once every 7.8 μs. Although a low refresh of 1-piled, 2-piled, or more piled refresh is input, the memory power control apparatus 100 according to an embodiment of the present inventive concept may recognize the refresh through its own counter as described below and control to increase the driving capability and response speed of the VPPEXT/VDD power only during the refresh period.

The number of refreshes input for the first time after transition of CKE from “L” to “H” after power-up may be counted and stored in the register 120 through the counter of refresh commands input into the memory module power control apparatus 100 for the first time. Therefore, as the memory module power control apparatus 100 may know at what time the refresh that is input thereafter will be input, the VDD/VPPEXT power reinforcement and response time can be increased in advance in preparation for the refresh input. At this point, the control unit 140 may increase the VDD/VPPEXT/VDDQ power reinforcement and response time through the setting of the MRS value and the DRAM parameters.

In addition, as the memory module power control apparatus 100 recognizes the refresh cycle, it may also know the power release section. At this point, the control unit 140 may minimize power by means of power release through the setting of the MRS value and the DRAM parameters.

The control unit 140 may control to increase the power of VPPEXT as the VPPEXT is used much to generate internal VPP of the memory 200 as soon as an active command is input, and increase the VDD power as the VDD uses much sensing current after several tens of ns. At this point, the control unit 140 may increase the VPPEXT/VDD power through the setting of the MRS value and the DRAM parameters.

Since transition of internal VPP power occurs after a precharge command is input, the control unit 140 increases power of the VPPEXT. At this point, the control unit 140 may increase power of the VPPEXT through the setting of the MRS value and the DRAM parameters.

When a memory write operation is input, data is input from a memory controller (not shown) after the set CWL. At this point, since the memory module power control apparatus 100 decodes the CWL of the MRS setting of the memory 200 in advance and stores the value in the register 120, the amount of VDDQ power supply and the response time may be increased before the write data is actually input into the DQ after waiting for the CWL interval after the write command is input. At this point, the control unit 140 may increase the amount of VDDQ power supply and the response time through the setting of the MRS value and the DRAM parameters.

When a memory read operation is input, data is output from the DRAM after the set CL. At this point, since the memory module power control apparatus 100 decodes the CL of the MRS setting of the memory 200 in advance and stores the value in the register 120, the amount of VDDQ power supply and the response time may be increased before the read data is actually output to the DQ after waiting for the CL interval after the read command is input. At this point, the control unit 140 may increase the amount of VDDQ power supply and the response time through the setting of the MRS value and the DRAM parameters.

As described above, as the memory module power control apparatus 100 according to an embodiment of the present inventive concept may prepare for current consumption suitable for each operation by changing internal settings in advance during normal operation of the memory such as DRAM, malfunctions due to current shortage or overcurrent can be minimized.

The control unit 140 may control to minimize the output of the regulator 130 between a previous refresh command set and a next refresh command set. That is, the control unit 140 may control to minimize the driving force to monitor loss of power between the previous command set and the next command set by using results of REFab, REFpb, and REFsb generation cycles among the memory commands.

At this point, in response to the refresh command, the control unit 140 may control driving of the regulator 130 by the parameter stored in the register 120 to be enabled before the refresh operation of the memory 200 according to execution of the refresh command, and disabled after the refresh operation of the memory 200 is completed.

In addition, the control unit 140 may control the driving time point of the regulator 130 for a write command and a read command considering the CWL and CL. That is, the control unit 140 may control to increase the amount of VDDQ power supply and the response time after the CWL and CL intervals when a write command and a read command are input.

As described above, as the memory module power control apparatus 100 according to an embodiment of the present inventive concept may minimize power consumption by selectively enabling the driving circuit or controlling the driving time point according to a command operation, cost can be reduced by reducing current consumption of the entire system.

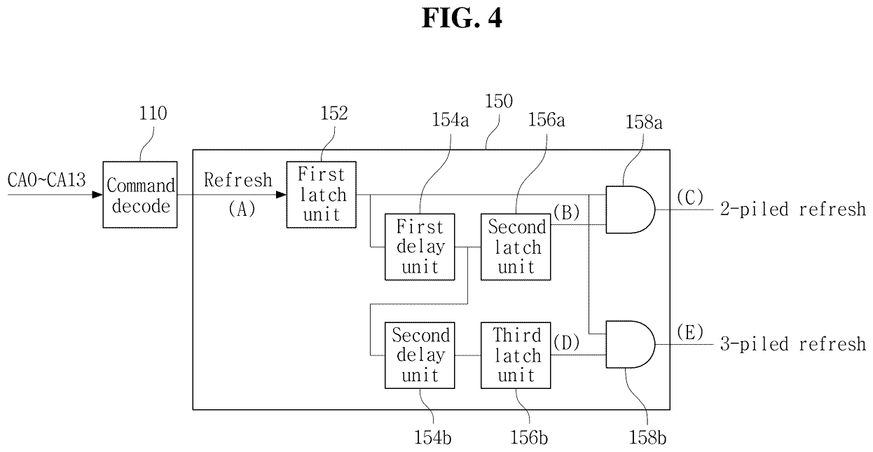

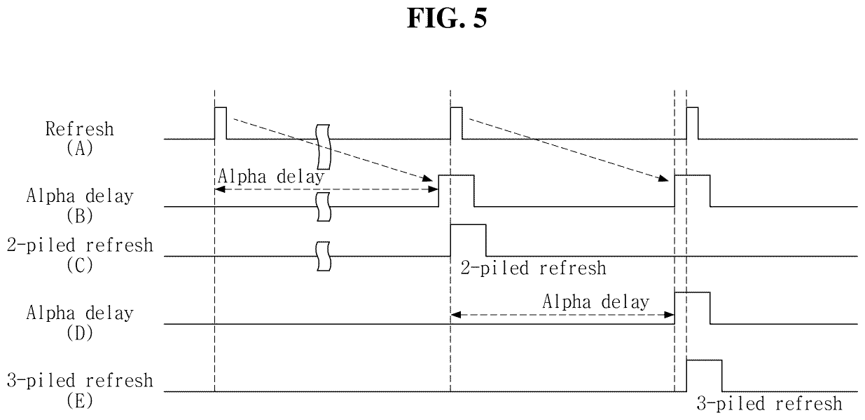

FIG. 4 is a view showing the configuration of a refresh count unit of a memory module power control apparatus according to an embodiment of the present inventive concept, and FIG. 5 is a timing diagram for explaining the refresh count of a memory module power control apparatus according to an embodiment of the present inventive concept.

Referring to FIG. 4, the memory module power control apparatus 100 may further include a counter 150 that counts the generation time of refresh. The control unit 140 may set the register 120 to adjust the output of the regulator 130 according to the number of refreshes counted by the counter 150.

The counter 150 may count the number of refreshes input at tREFC intervals. The counter 150 may include latch units 152 and 156, a delay unit 154, and an AND operation unit 158.

A first latch unit 152 may latch the refresh command through the command decoder 110. For example, the first latch unit 152 may be a flip-flop latch. Here, the command decoder 110 may receive a memory command through the command lines CA0 to CA13 and output a refresh signal to the counter 150 when the corresponding command is a refresh.

A first delay unit 154a may generate a delay signal by performing an alpha delay. Here, the alpha delay is a delay corresponding to tREFC (or tRFCI) and may be changed by setting the register 120.

A second latch unit 156a may latch the output signal of the first delay unit 154a. For example, the second latch unit 156a may be a flip-flop latch.

A first AND operation unit 158a may perform an AND operation on the second refresh signal of the first latch unit 152 and the output signal of the second latch unit 156a. At this point, an AND signal is generated as the second refresh signal of the first latch unit 152 and the output signal of the second latch unit 156a overlap. That is, the first AND operation unit 158a may generate a 2-piled refresh signal.

A second delay unit 154b may generate a delay signal, which is an alpha-delayed delay signal of the first delay unit 154a.

A third latch unit 156b may latch the output signal of the second delay unit 154b. For example, the third latch unit 156b may be a flip-flop latch.

A second AND operation unit 158b may perform an AND operation on a third refresh signal of the first latch unit 152 and the output signal of the third latch unit 156b. At this point, an AND signal is generated as the third refresh signal of the first latch unit 152 and the output signal of the third latch unit 156b overlap. That is, the second AND operation unit 158b may generate a 3-piled refresh signal.

Although it is described in FIG. 4 that the counter 150 generates a counter of the 3-piled refresh signal, counting of up to 8-piled refresh signals may be performed through additional expansion of the delay unit, the latch unit, and the AND operation unit.

Referring to FIG. 5, the command decoder 110 detects the first refresh, and the counter 150 counts (A) the first refresh.

When the second refresh is generated after tREFC (or tREFI), an AND signal is generated as the second refresh signal and the alpha-delayed signal overlap, and accordingly, a 2-piled refresh signal (C) may be generated.

When the third refresh is not generated thereafter, as the 2-piled refresh signal is latched and the next refresh signal is generated after 3.9 μs×2=7.8 μs, the memory module power control apparatus 100 may change the setting of the register 120 for the next refresh operation after 7.8 μs.

On the contrary, when the third refresh is generated, a 3-piled refresh signal (E) may be generated as a twice alpha-delayed signal (D) and an AND signal are generated.

At this point, since the next refresh signal is generated after 3.9 μs×3=11.7 μs, the memory module power control apparatus 100 may change the setting of the register 120 for the next refresh operation after 11.7 μs.

As described above, as the memory module power control apparatus 100 according to an embodiment of the present inventive concept may operate stably by using internal resources of the PMIC by counting the number of refreshes and adjusting the output according to the number of refreshes, power consumption of the PMIC can be minimized, and therefore, as the memory module power control apparatus 100 may operate stably by utilizing the internal resources, stability of products can be improved.

Meanwhile, the present inventive concept may be applied to change the setting of the magnitude and response speed of the final output of the power circuit provided inside the DRAM. That is, in the present inventive concept, as a command decoder is installed inside a memory such as DRAM or the like, and a circuit for decoding, latching, and counting refresh commands input from a memory controller (not shown) is added inside the memory, the setting of the magnitude and response speed of the final output of the power circuit provided inside the DRAM may be changed to an output that is input into the register by counting the number of refreshes input at tREFC (or tREFi) intervals.

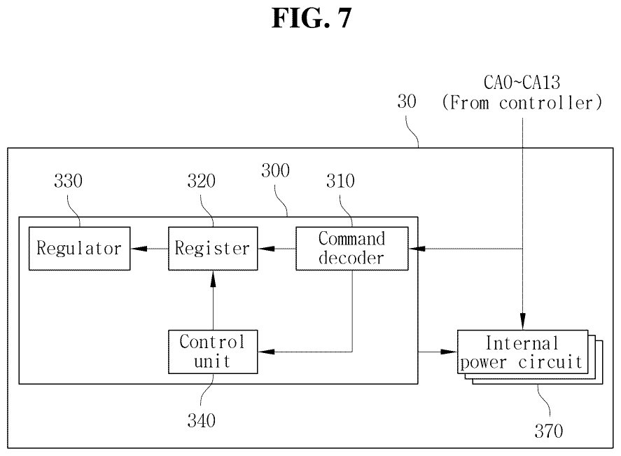

FIG. 7 is a view showing the configuration of a memory having a memory power control apparatus according to another embodiment of the present inventive concept.

Referring to FIG. 7, a memory power control apparatus 300 according to another embodiment of the present inventive concept includes a command decoder 310, a register 320, a regulator 330, and a control unit 340.

The memory power control apparatus 300 is a circuit embedded in a memory of DDR5 or higher, which can control the power driving capability and response time of the internal power circuit 370 of the memory suitable for each memory operation by decoding a command using a command line (CMD Line) input from a memory controller (not shown). Here, the memory 30 may support DDR5 or higher. At this point, the memory 30 may be all types of memory including DRAM.

To satisfy these specifications, the memory power control apparatus 300 may increase by itself the driving capability of the internal power circuit 370 of the DRAM and speed up the response speed according to operation of the memory 30.

Although embodiments of the present inventive concept have been described above, the spirit of the present inventive concept is not limited to the embodiments presented in this specification, and those skilled in the art who understand the spirit of the present inventive concept will be able to easily propose other embodiments by providing, changing, deleting, or adding components within the scope of the same spirit, and this will also be considered as falling within the scope of the spirit of the present inventive concept.

1. A memory module power control apparatus comprising:
a command decoder connected with a command line to decode a memory command transferred from a memory controller to a memory;
a regulator for supplying current to the memory;
a register for storing a parameter that adjusts an output of the regulator; and
a control unit for controlling to set and store the parameter in the register according to the memory command input into the memory on the basis of the decoded command.

2. The apparatus according to claim 1, wherein the command includes a Mode Register Write (MRW) command, a refresh command, a write command, a read command, and an active/precharge command.

3. The apparatus according to claim 2, wherein the control unit sets the register according to the MRW command, and sets the register to adjust the output of the regulator according to the refresh command, the write command, the read command, and the active/precharge command.

4. The apparatus according to claim 3, further comprising a counter for counting the number of generating the refresh transferred to the memory, wherein the control unit sets the register to adjust the output of the regulator according to the number of refreshes counted by the counter.

5. The apparatus according to claim 3, wherein the control unit controls to minimize the output of the regulator between a previous refresh command set and a next refresh command set, controls driving of the regulator by the parameter stored in the register to be enabled before a refresh operation of the memory according to execution of the refresh command and disabled after the refresh operation of the memory is completed in response to the refresh command, and controls a driving time point of the regulator for the write command and the read command by considering Write Latency (CWL) and Read Latency (CL).

6. A memory power control apparatus comprising:
a command decoder provided in a memory to decode a memory command transferred from a memory controller;
a regulator for supplying current to a power circuit provided inside the memory;
a register for storing a parameter that adjusts an output of the regulator; and
a control unit for controlling to set and store the parameter in the register according to the memory command input into the memory on the basis of the decoded command.
